(19) United States
(12) Patent Application Publication
(10) Pub. No.: US 2013/0320289 A1
(43) Pub. Date: Dec. 5, 2013

(54) RESISTANCE RANDOM ACCESS MEMORY AND METHOD OF FABRICATING THE SAME

(71) Applicants: Wei-Su Chen, Hsinchu City (TW); Tai-Yuan Wu, Taipei City (TW); Frederick T. Chen, Hsinchu County (TW); Pang-Hsu Chen, Hsinchu City (TW)

(72) Inventors: Wei-Su Chen, Hsinchu City (TW); Tai-Yuan Wu, Taipei City (TW); Frederick T. Chen, Hsinchu County (TW); Pang-Hsu Chen, Hsinchu City (TW)

(73) Assignee: INDUSTRIAL TECHNOLOGY RESEARCH INSTITUTE, Hsinchu (TW)

(21) Appl. No.: 13/612,844

(22) Filed: Sep. 13, 2012

(30) Foreign Application Priority Data
May 31, 2012 (TW) 101119681

(51) Int. Cl. H01L 45/00

(52) U.S. Cl. 257/4; 438/382; 257/E45.003

(57) ABSTRACT

A resistance random access memory including a first electrode layer, a second electrode layer, and a stacked structure is provided. The stacked structure includes a HfZrON layer and a ZrON layer and is located between the first electrode layer and the second electrode layer. In addition, the disclosure further provides a method of fabricating a resistance random access memory.

### CROSS-REFERENCE TO RELATED APPLICATION

This application claims the priority benefit of Taiwan application serial no. 101119681, filed on May 31, 2012. The entirety of the above-mentioned patent application is hereby incorporated by reference herein and made a part of this specification.

### TECHNICAL FIELD

The disclosure relates to a resistance random access memory (RRAM) and a method of fabricating the same.

### BACKGROUND

A resistance random access memory (RRAM), having a high memory density (minimum unit area of storage) and a high operation speed and requiring a low power consumption and low costs, is a memory device that has been widely studied in recent years. RRAM uses a conversion of electrons and/or ions in a resistance conversion material to generate two completely different states of a high resistance state and a low resistance state so as to distinguish whether a memory storage unit is turned on or off.

A hafnium oxide RRAM has a good durability and a high switching speed and is one of the most eye-catching memory devices in next-generation non-volatile memory devices. However, a titanium/hafnium oxide RRAM used currently has a wide distribution of resistance values under a high resistance state (HRS), which poses a considerable restriction on an operation thereof.

### SUMMARY

The disclosure provides a RRAM including a first electrode layer, a second electrode layer, and a stacked structure. The stacked structure is located between the first electrode layer and the second electrode layer and includes a HfZrON layer and a ZrON layer, wherein the HfZrON layer is located between the first electrode layer and the ZrON layer, and the ZrON layer is located between the HfZrON layer and the second electrode layer.

The disclosure further provides a method of fabricating a RRAM, the method including forming a hafnium oxide layer on the first electrode layer and then forming a zirconium layer. Then, a second electrode layer is formed on the zirconium layer. Next, an annealing process is performed to make the zirconium layer react with the hafnium oxide layer to form a stacked structure between the first electrode layer and the second electrode layer, the stacked structure including a HfZrON layer and a ZrON layer, wherein the HfZrON layer is located between the first electrode layer and the ZrON layer, and the ZrON layer is located between the HfZrON layer and the second electrode layer.

The disclosure further provides another method of fabricating a RRAM, the method including providing a first electrode layer. A stacked structure is formed on the first electrode layer. The stacked structure includes a HfZrON layer and a ZrON layer. Then, a second electrode layer is formed on the stacked structure. The HfZrON layer is located between the first electrode layer and the ZrON layer, and the ZrON layer is located between the HfZrON layer and the second electrode layer. The HfZrON layer and the ZrON layer are formed by deposition process.

In order to make the aforementioned features and advantages of the disclosure more comprehensible, embodiments accompanying figures are described in detail below.

### BRIEF DESCRIPTION OF THE DRAWINGS

The accompanying drawings are included to provide further understanding and are incorporated in and constitute a part of this specification. The drawings illustrate exemplary embodiments and, together with the description, serve to explain the principles of the disclosure.

FIG. 1 illustrates a schematic view of a resistance random access memory (RRAM) according to an embodiment of the disclosure.

FIGS. 2A to 2F are schematic flowcharts illustrating a fabricating process of a RRAM according to the first embodiment of the disclosure.

FIG. 3A illustrates a spectrogram detected by an X-ray energy dispersive spectrometer (EDS) in Comparative Example 1.

FIG. 3B illustrates a spectrogram detected by an X-ray energy dispersive spectrometer (EDS) in Experiment 1.

FIG. 4 illustrates a characteristic curve diagram of a forming current-voltage of Experiment 1 and Comparative Examples 1 to 4.

FIG. 5 illustrates a characteristic curve diagram of a resistance switching current-voltage of Experiment 1 and Comparative Examples 1 to 4.

FIG. 6 illustrates a distribution diagram of an average maximum reset current of Experiment 1 and Comparative Examples 1 to 4.

FIG. 7 illustrates a distribution diagram of a reset/set voltage of Experiment 1 and Comparative Examples 1 to 4.

FIG. 8 illustrates a distribution diagram of a high resistance (R_{high})/low resistance (R_{low}) of Experiment 1 and Comparative Examples 1 to 4.

FIG. 9A illustrates an endurance characteristic curve diagram of Experiment 1.

FIG. 9B illustrates an endurance characteristic curve diagram of Comparative Example 1.

FIG. 10A illustrates a data retention characteristic curve diagram of Experiment 1 measured at 85° C.

FIG. 10B illustrates a data retention characteristic curve diagram of Comparative Example 1 measured at 85° C.

FIG. 11 illustrates a forming voltage diagram of memory cells of various sizes which undergo a rapid thermal annealing at various temperatures in Experiment 2.

FIG. 12 illustrates an initial leakage current diagram of memory cells of various sizes which undergo a rapid thermal annealing at various temperatures in Experiment 2.

FIG. 13A illustrates an X-ray photoelectron spectrogram of Comparative Example 1.

FIG. 13B illustrates an X-ray photoelectron spectrogram of Experiment 1.

FIGS. 14A, 14B, 14C, 14D, 14E, 14F, 14G and 14H illustrate X-ray photoelectron spectrograms of O1s, Ti2p, Zr3d5 (ZrO2), Zr3d5 (Zr—Zr), Zr3d5 (Zr—N), Hf4f7 (Hf—N), Hf4f7 (Hf—O) and N1s of Experiment 1 and Comparative Example 1.

### DETAILED DESCRIPTION OF DISCLOSED EMBODIMENTS

FIG. 1 illustrates a schematic view of a resistance random access memory (RRAM) according to an embodiment of the disclosure.

Referring to FIG. 1, a RRAM of the disclosure includes a first electrode layer 10, a second electrode layer 30, and a stacked structure 20.

A material of the first electrode layer 10 is, for example, a metal or a metal nitride, including conductive materials such as platinum (Pt), iridium (Ir), titanium, titanium nitride (TiN), tantalum, tantalum nitride (TaN), tungsten (W), tungsten nitride (WN) or any combination thereof. A material of the second electrode layer 30 is, for example, a metal or a metal nitride, including conductive materials such as platinum, iridium, titanium, titanium nitride, tantalum, tantalum nitride, tungsten, tungsten nitride or any combination thereof.

The stacked structure 20 is located between the first electrode layer 10 and the second electrode layer 30. The stacked structure 20, the first electrode layer 10 and the second electrode layer 30 form a metal-insulator-metal (MIM) structure. The stacked structure 20 at least includes a hafnium zirconium oxynitride (HfZrON) layer 24 and a zirconium oxynitride (ZrON) layer 26. The HfZrON layer 24 may be composed of a single material layer. The HfZrON layer 24 may also include a first material layer 24a and a second material layer 24b, and a mole ratio of nitrogen, oxygen, zirconium and hafnium in the first material layer 24a is different from a mole ratio of nitrogen, oxygen, zirconium and hafnium in the second material layer 24b. In an embodiment, a material of the first electrode layer 10 and the second electrode layer 30 includes a titanium nitride. In addition to including the HfZrON layer 24 and the ZrON layer 26, the stacked structure 20 further includes a hafnium titanium oxynitride (HfTiON) layer 22 and a zirconium titanium nitride (ZrTiN) layer 28. The HfTiON layer 22 is located between the first electrode layer 10 and the HfZrON layer 24. The ZrTiN layer 28 is located between the ZrON layer 26 and the second electrode layer 30.

The stacked structure 20 may be formed by deposition process or by reaction.

Referring to FIG. 1, in an embodiment, a method of fabricating the RRAM of the disclosure includes providing the first electrode layer 10. The material of the first electrode layer 10 is, for example, a metal or a metal nitride, including conductive materials such as platinum, iridium, titanium, titanium nitride, tantalum, tantalum nitride, tungsten, tungsten nitride or any combination thereof.

Then, the stacked structure 20 is formed on the first electrode layer 10 by deposition process. The stacked structure 20 includes at least the HfZrON layer 24 and the ZrON layer 26. The HfZrON layer 24 may be composed of a single material layer. The HfZrON layer 24 may also include the first material layer 24a and the second material layer 24b, and the mole ratio of nitrogen, oxygen, zirconium and hafnium in the first material layer 24a is different from the mole ratio of nitrogen, oxygen, zirconium and hafnium in the second material layer 24b. The HfZrON layer 24 and the ZrON layer 26 may be formed sequentially by deposition process, such as physical vapor deposition, chemical vapor deposition, or atomic layer deposition.

In addition to including the HfZrON layer 24 and the ZrON layer 26, the stacked structure 20 further includes the HfTiON layer 22 and the ZrTiN layer 28. The HfTiON layer 22 is located between the first electrode layer 10 and the HfZrON layer 24. The ZrTiN layer 28 is located between the ZrON layer 26 and the second electrode layer 30. The HfTiON layer 22, the HfZrON layer 24, the ZrON layer 26, and the ZrTiN layer 28 of the stacked structure 20 may be formed sequentially by deposition process, such as physical vapor deposition, chemical vapor deposition, or atomic layer deposition.

Then, the second electrode layer 30 is formed on the stacked structure 20. The material of the second electrode layer 30 is, for example, a metal or a metal nitride, including conductive materials such as platinum, iridium, titanium, titanium nitride, tantalum, tantalum nitride, tungsten, tungsten nitride or any combination thereof.

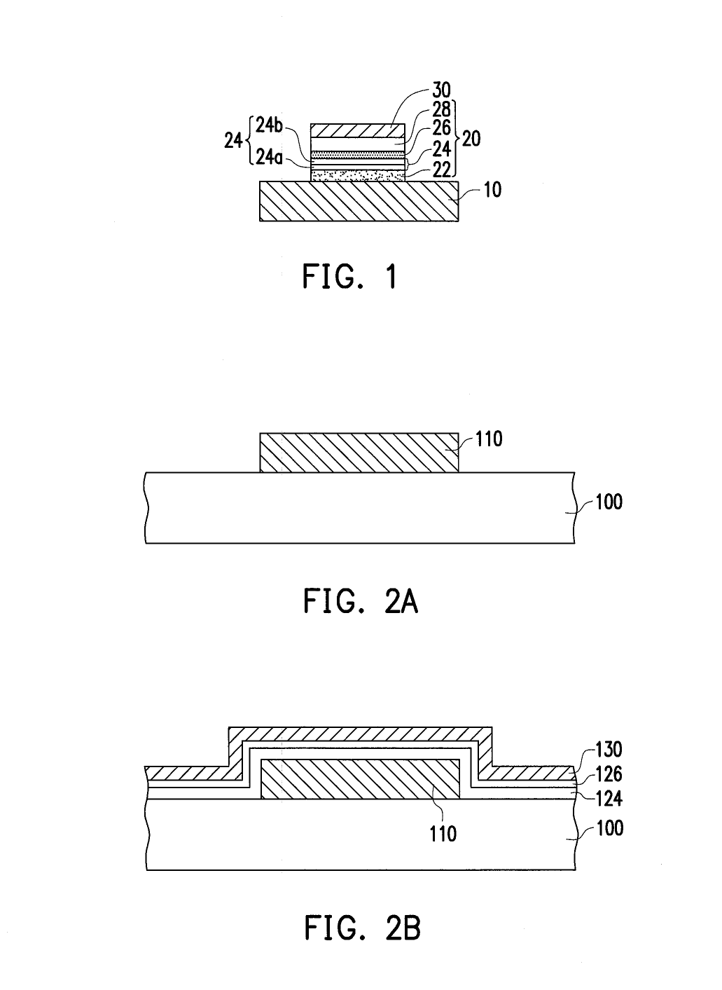

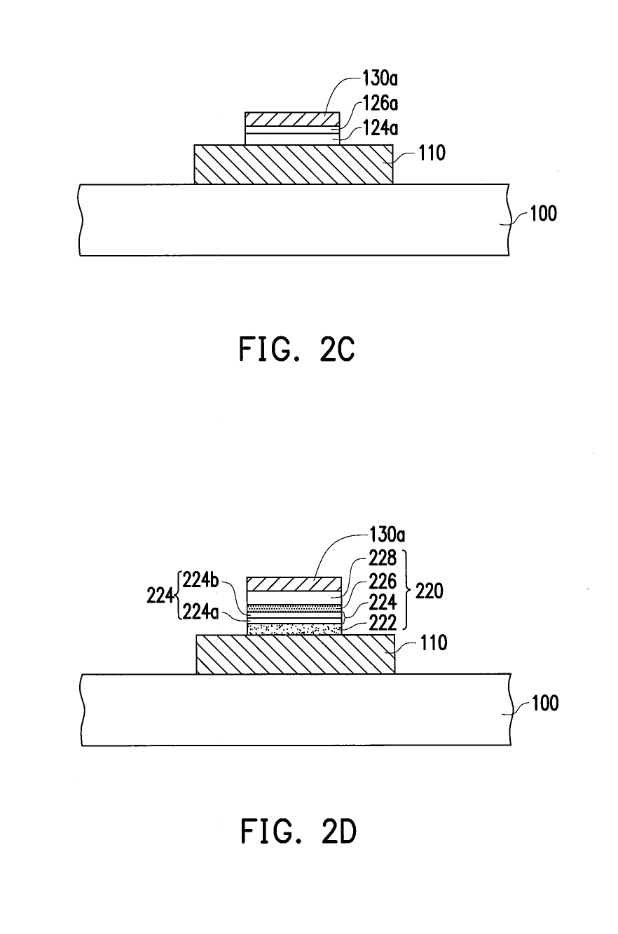

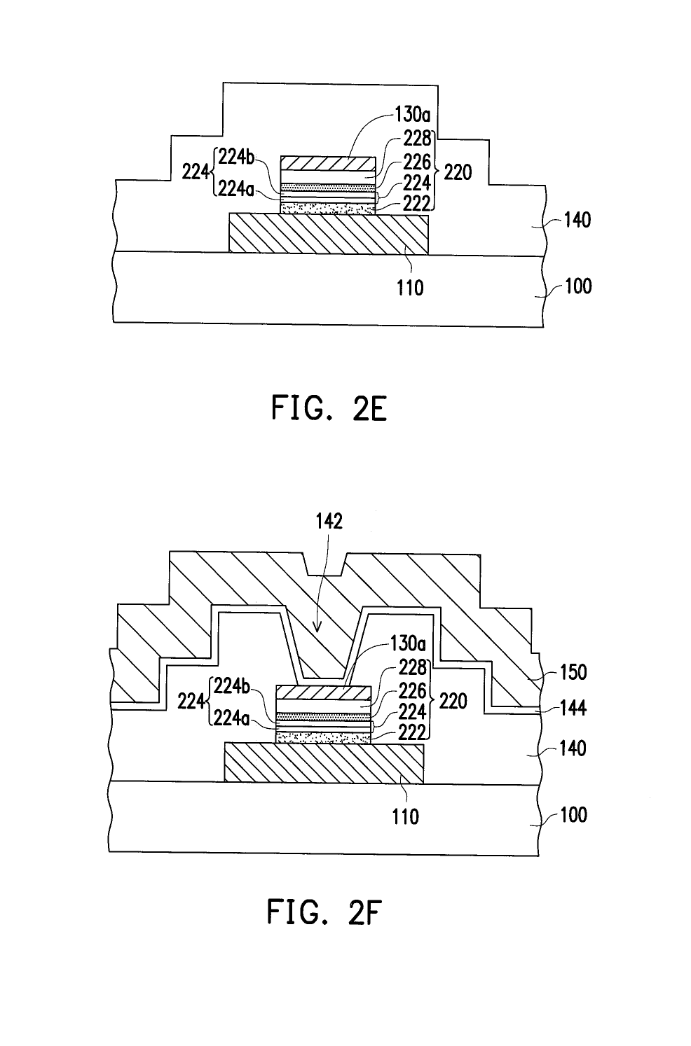

FIGS. 2A to 2F are schematic flowcharts illustrating a fabricating process of a RRAM according to an embodiment of the disclosure.

Referring to FIG. 2A, a first electrode layer 110 is formed on a substrate 100. A material of the substrate 100 includes an insulating layer, such as silicon oxide or an insulating layer on a semiconductor layer. The first electrode layer 110 may be a single-layered material layer or a double-layered material layer. A material of the first electrode layer 110 includes titanium nitride (Tiₓ₁N_{y1}), wherein x1:y1 is 1:2 to 1:1. A method of forming the first electrode layer 110 is, for example, forming a first electrode material layer (not shown) first, and patterning the first electrode material layer using a lithography and etching process.

Then, referring to FIG. 2B, a hafnium oxide (Hfₓ₂O_{y2}) layer 124 is formed on the first electrode layer 110, wherein x2:y2 is 1:2 to 1:1.5. A method of forming the hafnium oxide layer 124 may be physical vapor deposition such as sputtering, chemical vapor deposition, or atomic layer deposition. A thickness of the hafnium oxide layer 124 is, for example, about 1 to 10 nm. Thereafter, a zirconium layer 126 is formed on the hafnium oxide layer 124. A method of forming the zirconium layer 126 may be physical vapor deposition, such as sputtering, using pure zirconium as a target material. A thickness of the zirconium layer 126 is, for example, 1.6 to 3 times of the thickness of the hafnium oxide layer 124.

Then, a second electrode material layer 130 is formed on the hafnium oxide layer 124 and the zirconium layer 126. The second electrode material layer 130 may be a single-layered material layer or a double-layered material layer. A material of the second electrode material layer 130 includes titanium nitride.

Thereafter, referring to FIG. 2C, a lithography process and an etching process are performed to pattern the second electrode material layer 130, the zirconium layer 126 and the hafnium oxide layer 124, so as to form a second electrode layer 130a, a zirconium layer 126a and a hafnium oxide layer 124a.

Then, referring to FIG. 2D, an annealing process is performed to make the zirconium layer 126a react with the hafnium oxide layer 124a to form a HfTiON layer 222, a HfZrON layer 224, a ZrON layer 226, and a ZrTiN layer 228. The HfTiON layer 222, the HfZrON layer 224, the ZrON layer 226, and the ZrTiN layer 228 form a stacked structure 220. The HfZrON layer 224 may be composed of a single material layer. The HfZrON layer 224 may also include a first material layer 224a and a second material layer 224b, and a mole ratio of nitrogen, oxygen, zirconium and hafnium in the first material layer 224a is different from a mole ratio of nitrogen, oxygen, zirconium and hafnium in the second material layer 224b.

A process temperature of the annealing process is greater than or equal to 400° C. A highest temperature of the annealing process is adjusted according to actual requirements. When the RRAM is formed in a back-end process, and a metal line has been formed on the substrate 100 before the RRAM is formed, then the highest temperature of the annealing process has to be set with a melting point of the metal line taken into consideration. A gas introduced into the annealing process includes nitrogen or the annealing process is performed in vacuum. The process temperature of the annealing process is greater than or equal to 400° C. and less than or equal to 500° C. The annealing process includes a furnace annealing process or a rapid thermal annealing (RTA) process. In an embodiment, the annealing process is the furnace annealing process, and an annealing temperature is in a range form 400 to 500° C., and an annealing time is in a range form 1 to 10 minutes. In an embodiment, the annealing process is the rapid thermal annealing process, and an annealing temperature is in a range form 400 to 500° C., and an annealing time is in a range form 1 to 30 minutes.

Then, referring to FIG. 2E, a dielectric layer 140 is formed on the substrate 100 to cover the second electrode layer 130a, the stacked structure 220 and the first electrode layer 110. The dielectric layer 140 may be a single-layered material layer or a double-layered material layer. A material of the dielectric layer 140 includes silicon oxide, silicon nitride or any combination thereof. The annealing process may be performed after the dielectric layer 140 is formed.

Thereafter, referring to FIG. 2F, a lithography process and an etching process are performed to form a contact opening 142 in the dielectric layer 140 to expose a surface of the second electrode layer 130a. Then, a barrier layer 144 and a conductive layer 150 are formed on the dielectric layer 140. The barrier layer 144 and the conductive layer 150 are filled into the contact opening 142 to be electrically connected with the second electrode layer 130a. A material of the barrier layer 144 includes a metal nitride, such as titanium nitride or tantalum nitride. The conductive layer 150 includes a metal or a metal alloy, such as aluminum, copper, tungsten, or an alloy thereof.

In the embodiment, the first electrode layer 110 is viewed as a bottom electrode layer, and the second electrode layer 130a is viewed as a top electrode layer. The stacked structure 220 includes the HfTiON layer 222, the HfZrON layer 224, the ZrON layer 226, and the ZrTiN layer 228. The HfTiON layer 222, the HfZrON layer 224 and the ZrON layer 226 are insulating layers, and the ZrTiN layer 228 is a conductive layer.

A method of fabricating the stacked structure of the RRAM of the above embodiment may form the stacked structure including the HfTiON layer, the HfZrON layer, the ZrON layer, and the ZrTiN layer through the annealing process after the hafnium oxide layer and the zirconium layer are deposited; therefore, the fabrication process thereof is very simple. In addition, the required annealing time is in a ranged from 1 to 30 minutes, so the fabrication process is very quick. However, a method of forming the HfZrON layer and the ZrON layer of the disclosure is not limited to the above way of using reactions; the HfZrON layer and the ZrON layer may be formed by deposition process, such as physical vapor deposition, chemical vapor deposition, or atomic layer deposition.

Experiment 1

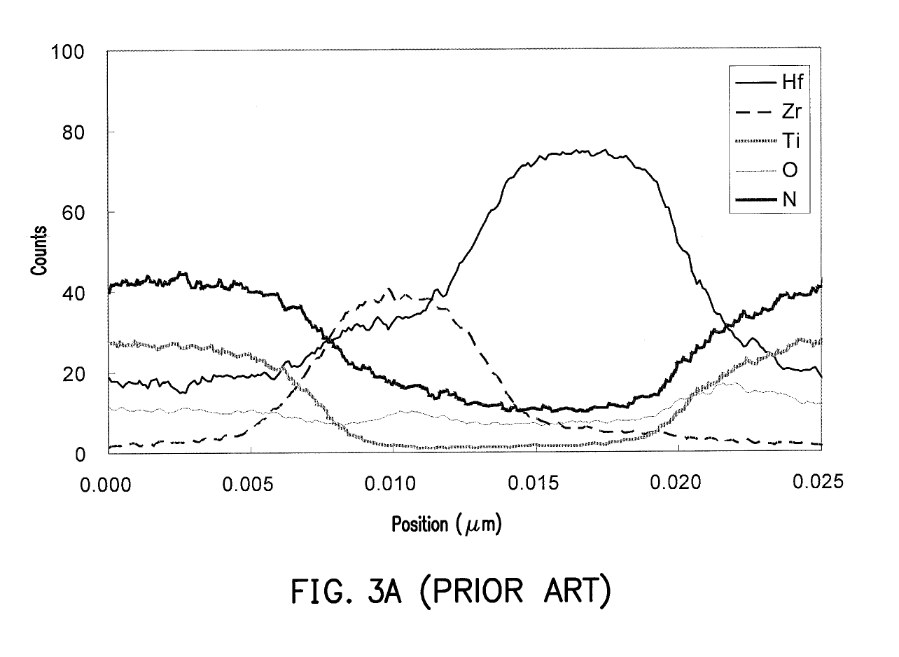

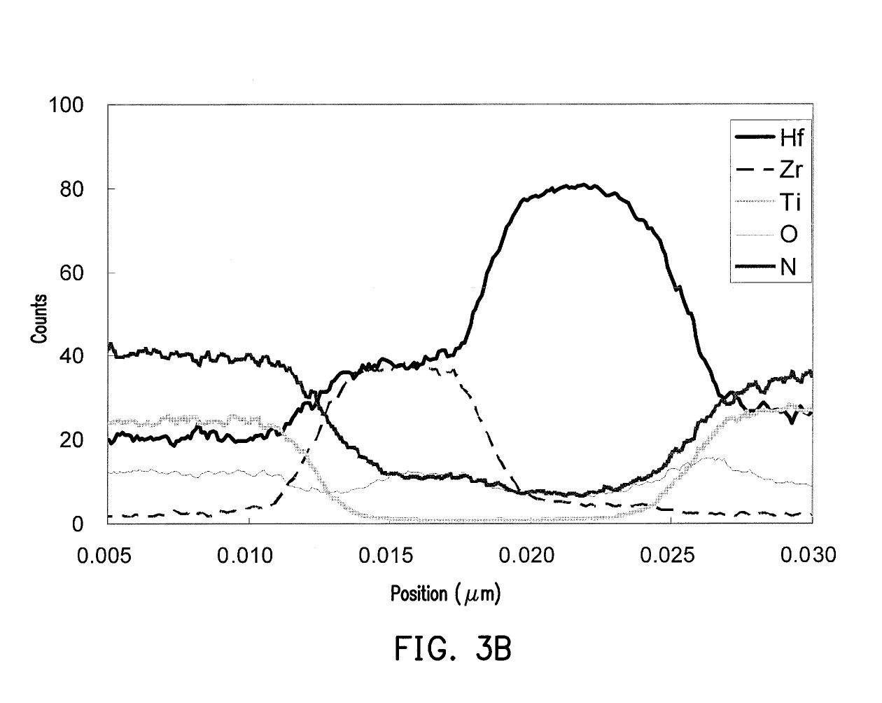

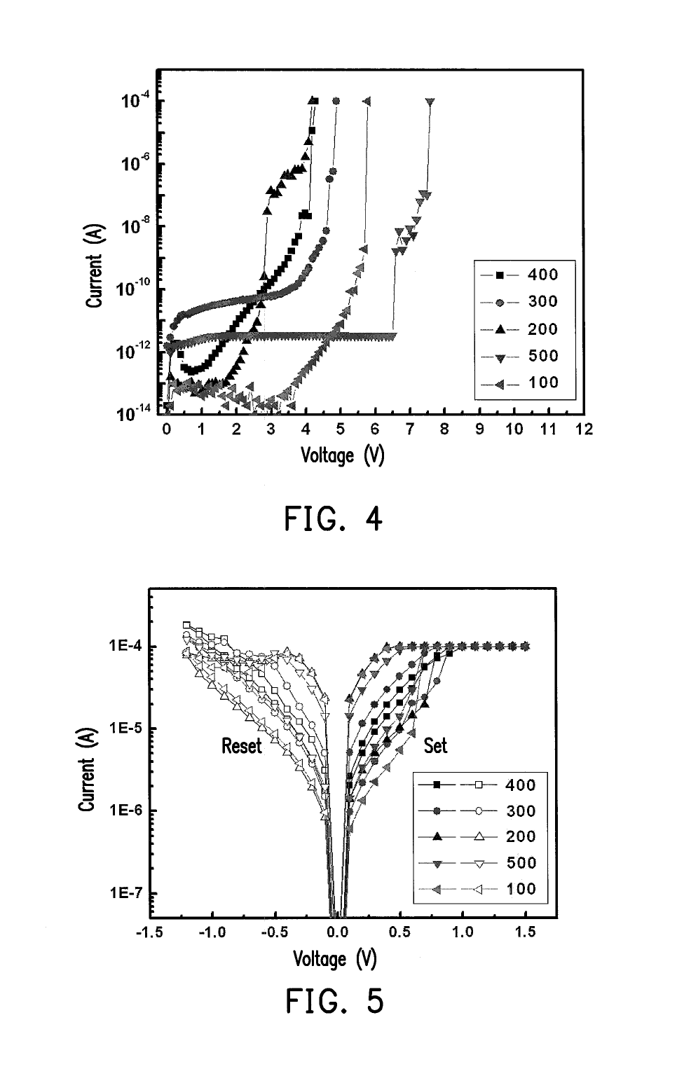

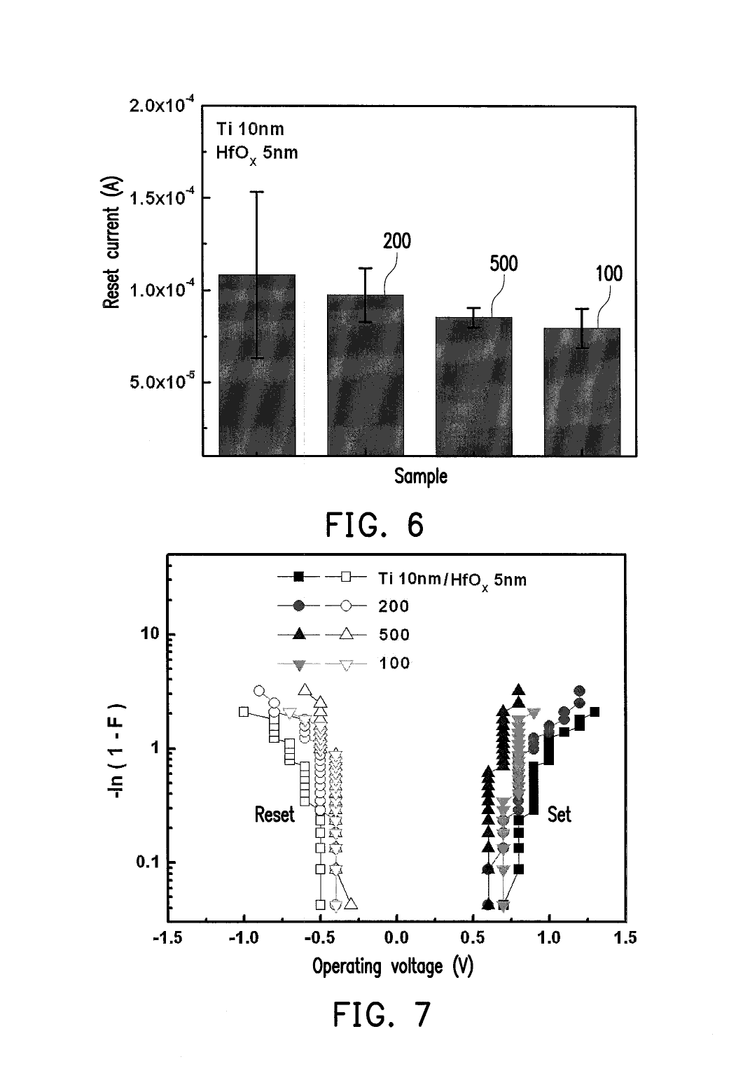

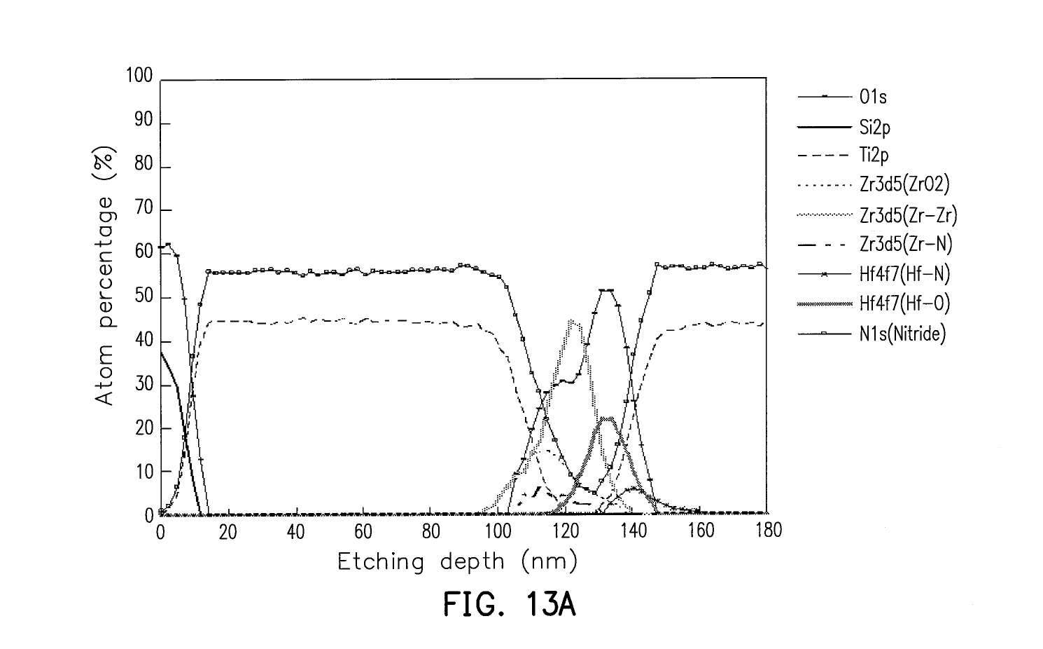

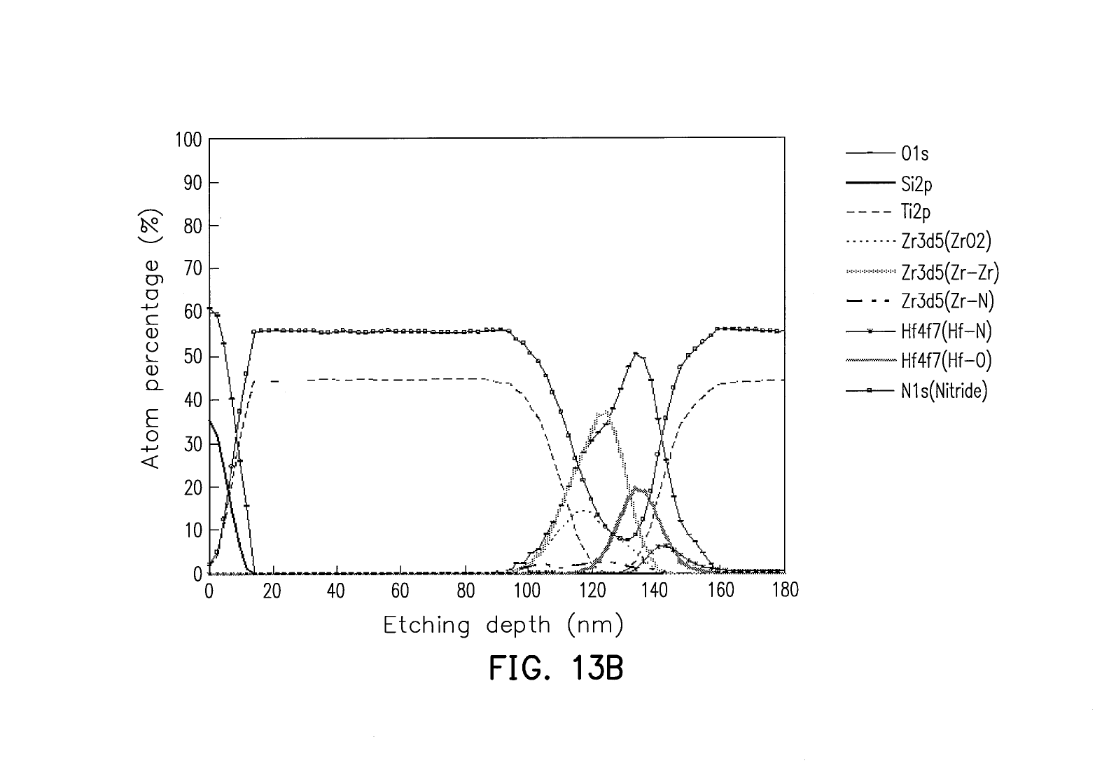

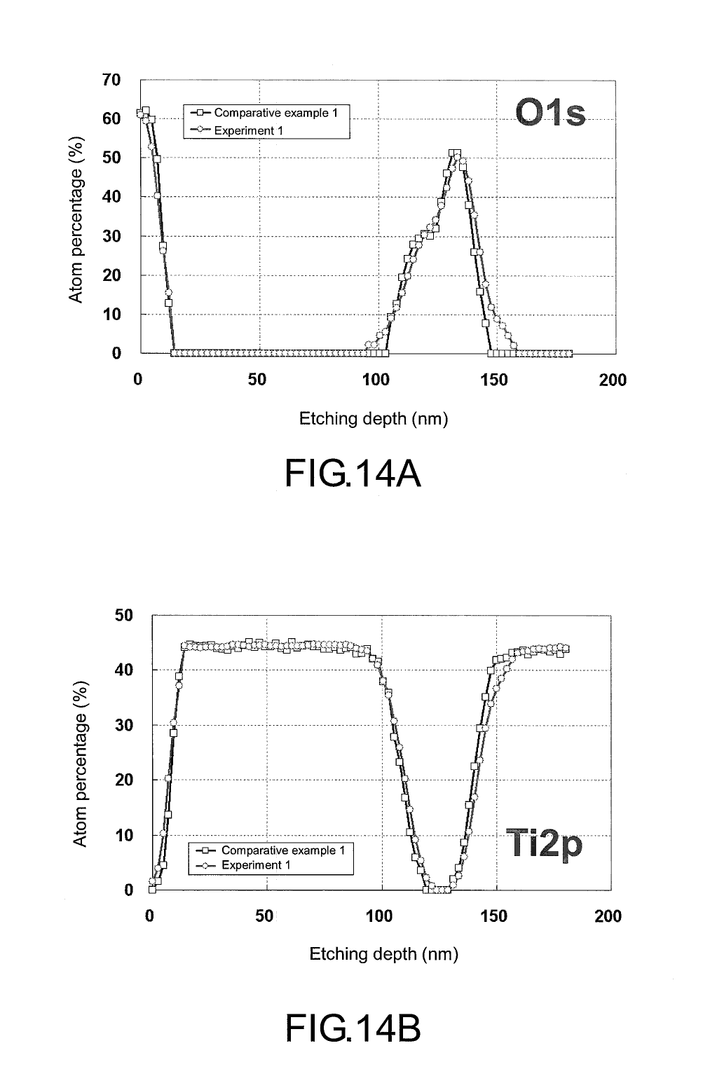

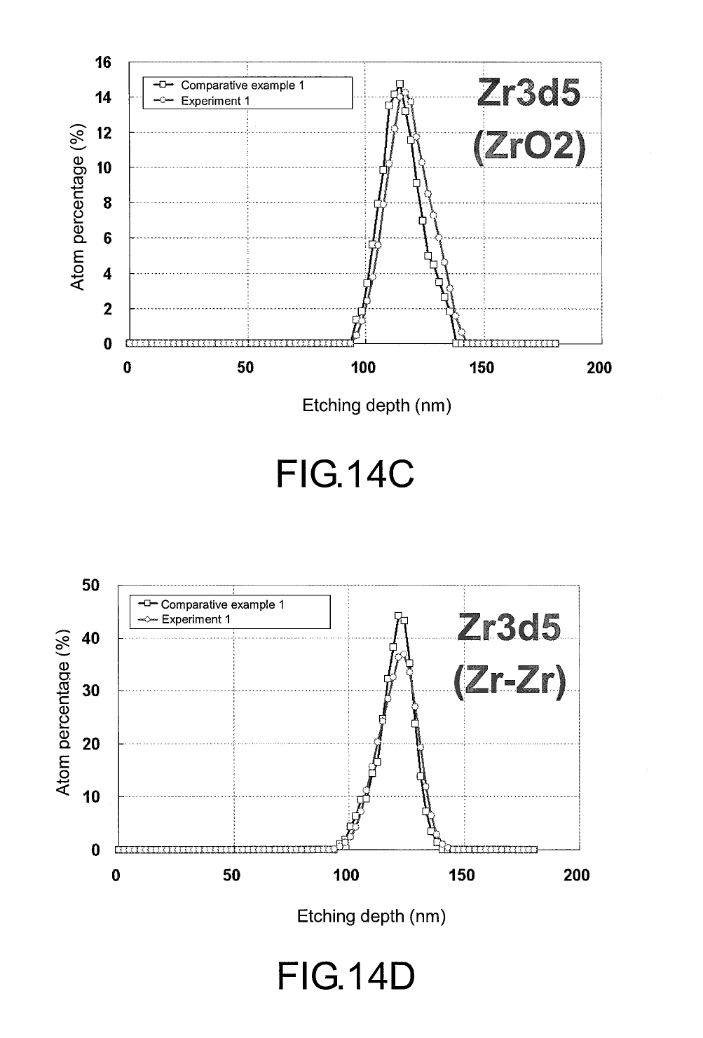

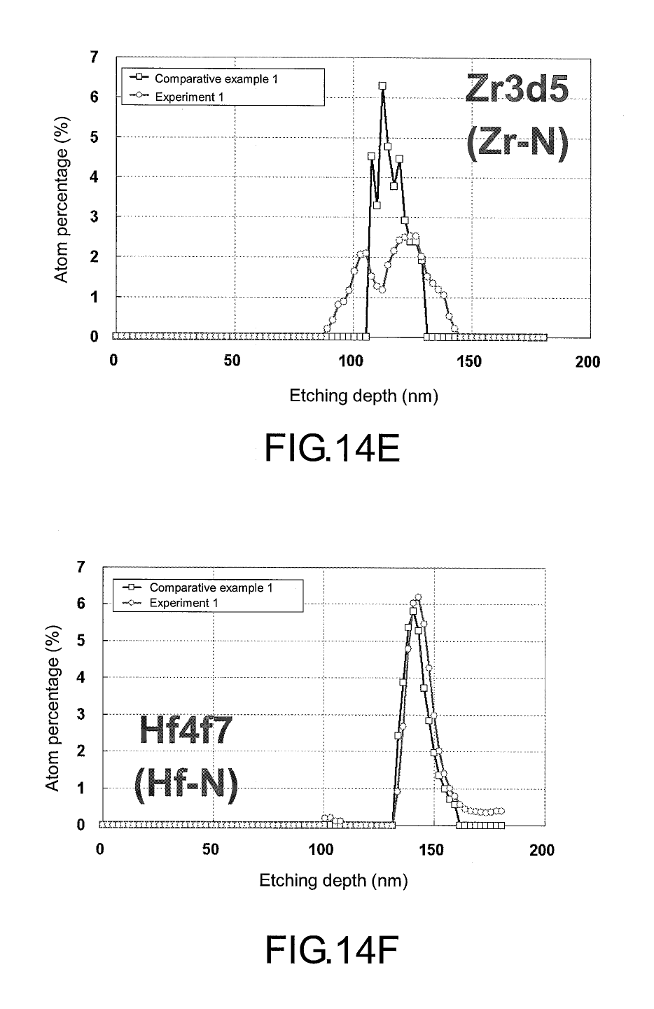

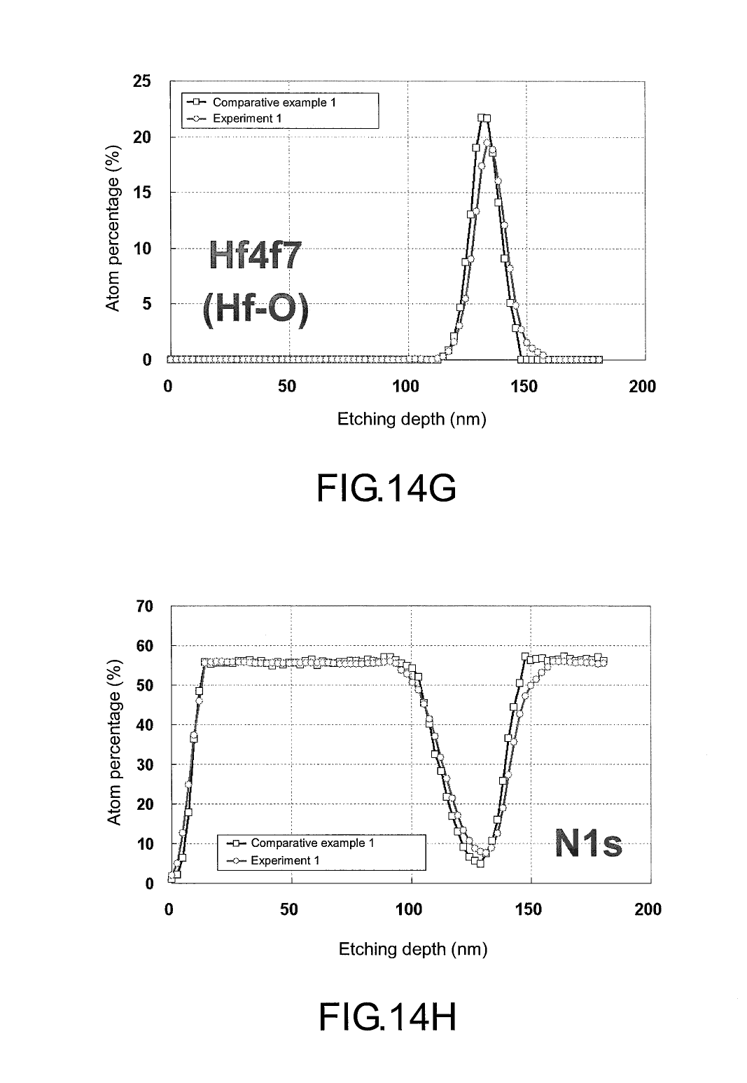

A 5 nm thick hafnium oxide layer and a 10 nm thick zirconium layer are sequentially deposited on a titanium nitride and titanium (TiN/Ti) bottom electrode, and then a titanium nitride top electrode is formed on the zirconium layer. Then, an annealing is performed for 5 minutes with a furnace process under a nitrogen gas ambiance at a temperature of 400° C. Then, a measurement is performed by an X-ray energy dispersive spectrometer (EDS), and results of the measurement are as shown in FIG. 3B. Next, an electrical test and an operating characteristic analysis are performed. Results of the electrical test are as shown by Curve 100 or by Line 100 in FIGS. 4-5. Results of the operating characteristic analysis are as shown by curves or by Curve 100 or by Line 100 in FIGS. 6-8 and FIGS. 9A-10A. The X-ray energy dispersive spectrometer detects a material composition structure at a depth of a film layer in the formed stacked structure, and results are as shown in FIG. 13B. X-ray photoelectron spectrograms of the formed stacked structure in O1s, Ti2p, Zr3d5 (ZrO2), Zr3d5 (Zr—Zr), Zr3d5 (Zr—N), Hf4f7 (Hf—N), Hf4f7 (Hf—O) and N1s are as shown in FIGS. 14A, 14B, 14C, 14D, 14E, 14F, 14G and 14H.

### COMPARATIVE EXAMPLE 1

According to the method of Experiment 1, a 5 nm thick hafnium oxide layer and a 10 nm thick zirconium layer are sequentially deposited on a TiN/Ti electrode, and then a titanium nitride electrode is formed. Then, the annealing process of Experiment 1 is not performed. Thereafter, a measurement is performed by the X-ray energy dispersive spectrometer (EDS), and results of the measurement are as shown in FIG. 3A. Next, an electrical test and an operating characteristic analysis are performed. Results of the electrical test are as shown by Curves 200 or by Line 200 in FIGS. 4-5. Results of the operating characteristic analysis are as shown by curves or by Line 200 in FIGS. 6-8 and FIGS. 9A-10A. The X-ray energy dispersive spectrometer detects a material composition structure at a depth of a film layer in the formed stacked structure, and results are as shown in FIG. 13A. X-ray photoelectron spectrograms of the formed stacked structure in O1s, Ti2p, Zr3d5 (ZrO2), Zr3d5 (Zr—Zr), Zr3d5 (Zr—N), Hf4f7 (Hf—N), Hf4f7 (Hf—O) and N1s are as shown in FIGS. 14A, 14B, 14C, 14D, 14E, 14F, 14G and 14H.

### COMPARATIVE EXAMPLE 2

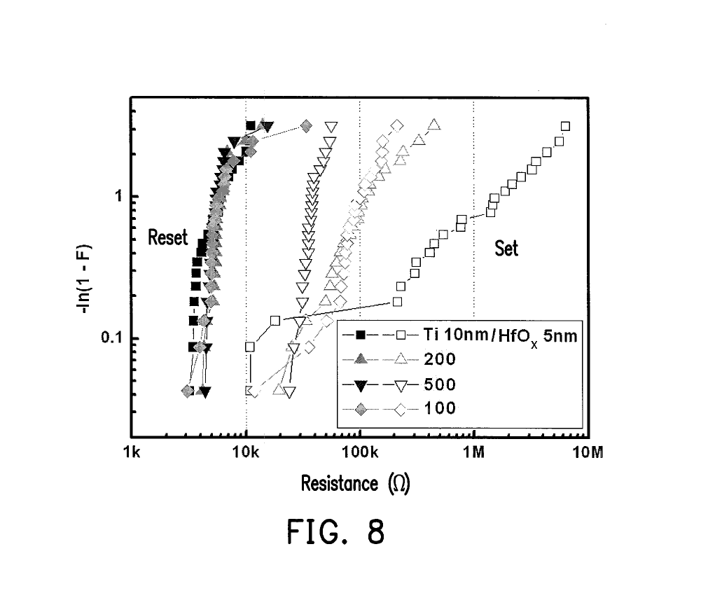

According to the method of Experiment 1, a 5 nm thick hafnium oxide layer and a 5 nm thick zirconium layer are sequentially deposited on a TiN/Ti electrode, and then a titanium nitride electrode is formed. Then, an annealing process is not performed. Next, an electrical test and an operating characteristic analysis are performed. Results of the electrical test are as shown by Curves 300 or by Line 300 in FIGS. 4-5. Results of the operating characteristic analysis are as shown by Curves or by Line 300 in FIGS. 7-8.

### COMPARATIVE EXAMPLE 3

According to the method of Experiment 1, a 3 nm thick hafnium oxide layer and a 5 nm thick zirconium layer are sequentially deposited on a TiN/Ti electrode, and then a titanium nitride electrode is formed. Then, an annealing process is not performed. Next, an electrical test and an operating characteristic analysis are performed. Results of the electrical test are as shown by Curves 400 or by Line 400 in FIGS. 4-5. Results of the operating characteristic analysis are as shown by Curves or by Line 400 in FIGS. 7-8.

### COMPARATIVE EXAMPLE 4

According to the method of Experiment 1, a 20 nm thick hafnium oxide layer and a 10 nm thick zirconium layer are sequentially deposited on a TiN/Ti electrode, and then a titanium nitride electrode is formed. Then, an annealing process is not performed. Next, an electrical test and an operating characteristic analysis are performed. Results of the electrical test are as shown by Curves 500 or by Line 500 in FIGS. 4-5. Results of the operating characteristic analysis are as shown by Curves 500 or by Line 500 in FIGS. 6-8.

Experiment 2

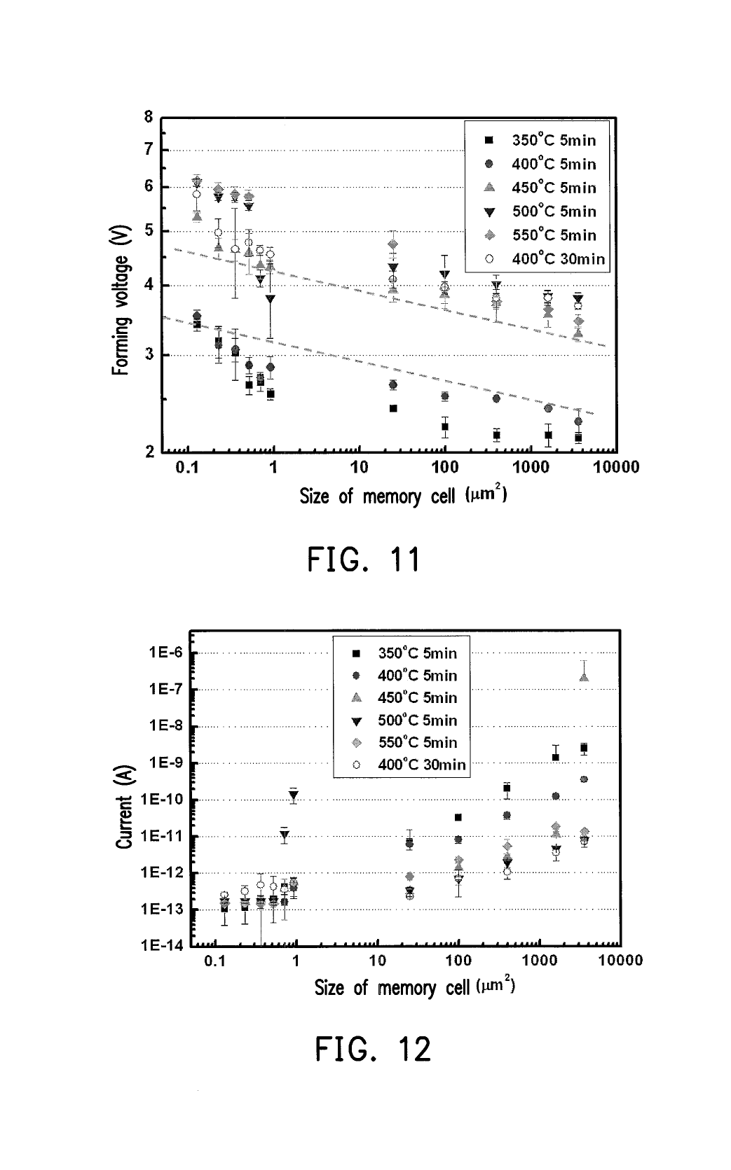

According to the method of Experiment 1, a 5 nm thick hafnium oxide layer and a 10 nm thick zirconium layer are sequentially deposited on a TiN/Ti electrode, and then a titanium nitride electrode is formed to fabricate memory cells of various sizes. Then, an annealing is performed with a rapid thermal annealing process under a nitrogen gas ambiance at various temperatures. Next, an electrical test is performed, and results thereof are as shown in FIGS. 11 and 12.

Compared with FIG. 3A, results of FIG. 3B show that after the annealing process, there are nitrogen, oxygen, hafnium and zirconium at about 0.015 micrometer. Therefore, a new material layer is judged to be formed between the titanium nitride top electrode and the hafnium oxide layer. The material layer contains nitrogen, oxygen, hafnium and zirconium and is called a hafnium zirconium oxynitride (HfZrON) layer.

In a current-voltage characteristic curve diagram shown in FIG. 4, results of Curve 100 and Curve 200 show that a forming voltage (breakdown voltage) of the RRAM of Experiment 1 with the annealing process significantly increases compared with a forming voltage of Comparative Example 1 without the annealing process. In addition, a leakage mechanism of the RRAM of Experiment 1 with the annealing process is completely different from a leakage mechanism of Comparative Example 1 without the annealing process. The results in FIG. 4 show that there is indeed a new material layer produced after the annealing process.

In a current-voltage characteristic curve diagram shown in FIG. 5, results of Curve 100 and Curve 200 show that a maximum reset current (Max RESET Current) in a negative voltage range of the RRAM with the annealing process (Experiment 1) may be minimized.

Results of Line 100 and Lines 200-500 in FIG. 6 show that a distribution of an average maximum reset current of the RRAM with the annealing process (Experiment 1) is clearly less than a distribution of an average maximum reset current of the RRAM without the annealing process and is less than a distribution of an average maximum reset current of a titanium/hafnium oxide RRAM. In addition, a variance of the RRAM with the annealing process (Experiment 1) is clearly less than a variance of the RRAM without the annealing process and is less than a variance of the titanium/hafnium oxide RRAM.

FIGS. 7 and 8 respectively illustrate a reset/set voltage distribution and a high resistance (R_{high})/low resistance (R_{low}) distribution. Results in FIGS. 7 and 8 show that a reset/set voltage distribution and a high resistance (R_{high})/low resistance (R_{low}) distribution of the RRAM with the annealing process (Experiment 1), though with some slight differences, is roughly similar to a reset/set voltage distribution and a high resistance (R_{high})/low resistance (R_{low}) distribution of the RRAM without the annealing process. F in ordinate in FIG. 7 represents a failure ratio of the Weibull distribution.

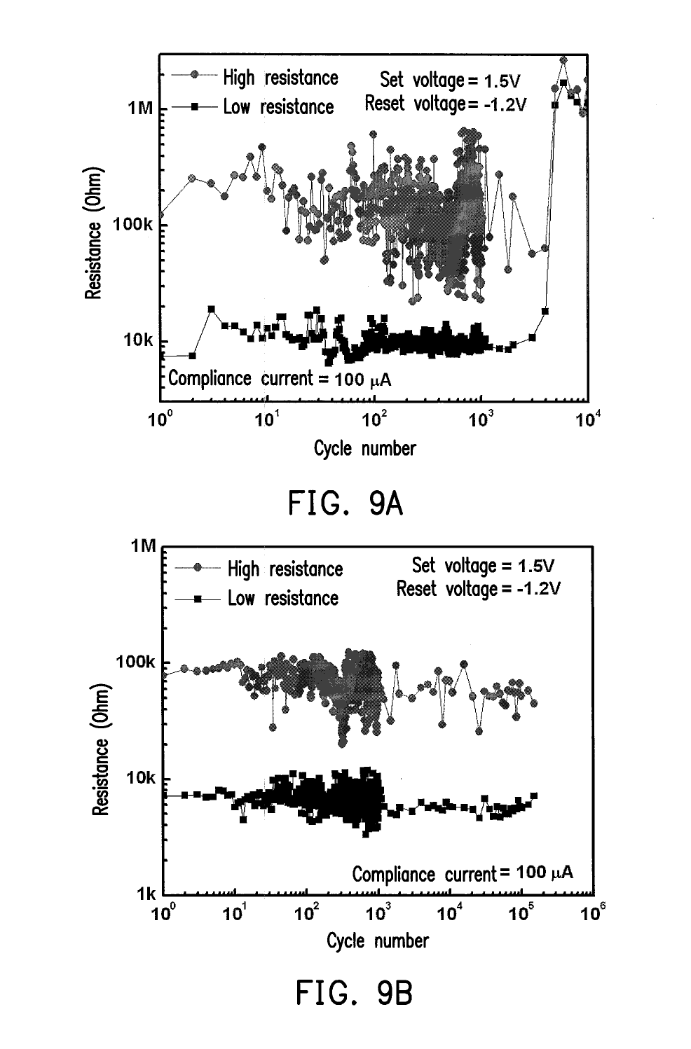

FIGS. 9A and 9B respectively illustrate endurance characteristic curve diagrams of Comparative Example 1 and Experiment 1. Results of FIGS. 9A and 9B show that the RRAM with the annealing process (Experiment 1) has a higher endurance cycling and more stable characteristics, which indicates that the formed new material, the HfZrON layer, is more stable in read and write operations.

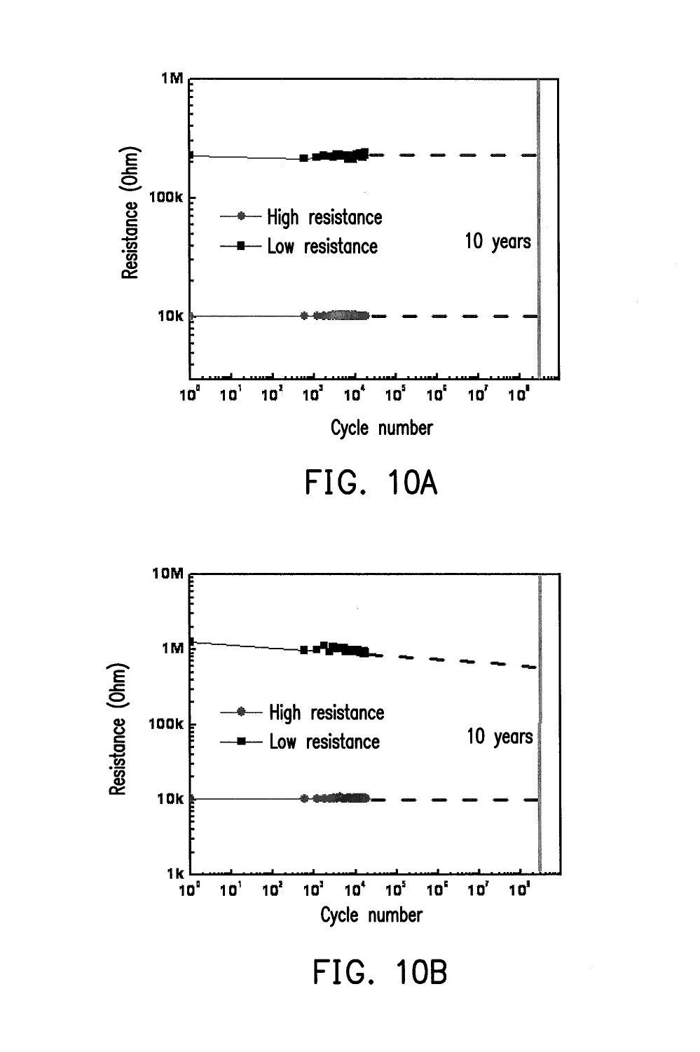

FIGS. 10A and 10B respectively illustrate data retention characteristic curve diagrams of Comparative Example 1 and Experiment 1. Results of FIGS. 10A and 10B show that under a temperature of 85° C., reliability of data storage of the two is both quite stable.

Results of FIGS. 11 and 12 show that for memory cells of various sizes, the annealing temperature greater than or equal to 400° C. greatly increases the forming voltage (breakdown voltage) and decreases a leakage current.

Bonding results obtained from FIGS. 13A and 14A-14H show that after the hafnium oxide layer, the zirconium layer and the titanium nitride top electrode are sequentially deposited on the bottom electrode composed of titanium nitride and titanium and before the annealing process is performed, the hafnium oxide layer reacts with the underlying titanium nitride layer after deposited to form a HfTiN layer and a HfON layer. After the zirconium layer is deposited, since the activity of zirconium is very high, the zirconium layer reacts with an interface of the HfON layer below to form two HfZrON layers which have different atomic mole ratios and a ZrON layer, and the zirconium itself may not oxidize and form an oxygen-doped zirconium layer.

The bonding results obtained from FIGS. 13B and 14A-14H show that after the hafnium oxide layer, the zirconium layer and the titanium nitride top electrode are sequentially deposited on the bottom electrode composed of titanium nitride and titanium and after the annealing process is performed, a HfTiON layer, and the two HfZrON layers which have different atomic mole ratios, the ZrON layer, and a ZrTiN layer are formed sequentially between the top electrode and the bottom electrode.

In summary of the above, because there is the HfZrON layer in the stacked structure between the two electrodes, the RRAM of the disclosure has a relatively stable and narrowly distributed reset/set voltage, high resistance, low resistance and maximum reset current, a good operational stability, and an endurance thereof reaches 10⁵ cycles, which prolongs the service life thereof. In addition, the RRAM of the disclosure forms the HfZrON layer by simply depositing the hafnium oxide layer and the zirconium layer and by the annealing process; the fabrication process is simple, and the time the fabrication process requires is relatively short.

Although the disclosure has been disclosed by the above embodiments, they are not intended to limit the disclosure. It will be apparent to those of ordinary skill in the art that modifications and variations to the disclosure may be made without departing from the spirit and the scope of the disclosure. Accordingly, the protection scope of the disclosure falls in the appended claims.

What is claimed is:

1. A resistance random access memory (RRAM), comprising:
a first electrode layer;
a second electrode layer; and
a stacked structure located between the first electrode layer and the second electrode layer, the stacked structure comprising a hafnium zirconium oxynitride (HfZrON) layer and a zirconium oxynitride (ZrON) layer, wherein the HfZrON layer is located between the first electrode layer and the ZrON layer, and the ZrON layer is located between the HfZrON layer and the second electrode layer.

2. The RRAM according to claim 1, wherein a material of the first electrode layer comprises platinum, iridium, titanium, titanium nitride, tantalum, tantalum nitride, tungsten, tungsten nitride or any combination thereof.

3. The RRAM according to claim 1, wherein a material of the second electrode layer comprises platinum, iridium, titanium, titanium nitride, tantalum, tantalum nitride, tungsten, tungsten nitride or any combination thereof.

4. The RRAM according to claim 1, wherein a material of the first electrode layer comprises titanium nitride, and the stacked structure further comprises a hafnium titanium oxynitride (HfTiON) layer located between the HfZrON layer and the first electrode layer.

5. The RRAM according to claim 4, wherein a material of the second electrode layer comprises titanium nitride, and the stacked structure further comprises a zirconium titanium nitride (ZrTiN) layer located between the ZrON layer and the titanium nitride of the second electrode layer.

6. The RRAM according to claim 1, wherein a material of the second electrode layer comprises titanium nitride, and the stacked structure further comprises a ZrTiN layer located between the ZrON layer and the titanium nitride of the second electrode layer.

7. The RRAM according to claim 1, wherein the HfZrON layer is composed of a single material layer.

8. The RRAM according to claim 1, wherein the HfZrON layer comprises a first material layer and a second material layer, and a mole ratio of nitrogen, oxygen, zirconium and hafnium in the first material layer is different from a mole ratio of nitrogen, oxygen, zirconium and hafnium in the second material layer.

9. A method of fabricating a resistance random access memory (RRAM), comprising:
forming a hafnium oxide layer on a first electrode layer;
forming a zirconium layer on the hafnium oxide layer;
forming a second electrode layer on the zirconium layer; and
performing an annealing process to make the zirconium layer react with the hafnium oxide layer to form a stacked structure between the first electrode layer and the second electrode layer, the stacked structure comprising a HfZrON layer and a ZrON layer, wherein the HfZrON layer is located between the first electrode layer and the ZrON layer, and the ZrON layer is located between the HfZrON layer and the second electrode layer.

10. The method of fabricating the RRAM according to claim 9, wherein a process temperature of the annealing process is greater than or equal to 400° C. and less than or equal to 500° C.

11. The method of fabricating the RRAM according to claim 9, wherein the annealing process comprises a furnace annealing process.

12. The method of fabricating the RRAM according to claim 11, wherein a process temperature of the annealing process is greater than or equal to 400° C.

13. The method of fabricating the RRAM according to claim 9, wherein the annealing process comprises a rapid thermal annealing process.

14. The method of fabricating the RRAM according to claim 13, wherein a process temperature of the annealing process is greater than or equal to 400° C.

15. The method of fabricating the RRAM according to claim 9, wherein materials of the first electrode layer and the second electrode layer comprise metal nitrides.

16. The method of fabricating the RRAM according to claim 15, wherein the material of the first electrode layer comprises titanium nitride, and the stacked structure further comprises a HfTiON layer located between the HfZrON layer and the first electrode layer.

17. The method of fabricating the RRAM according to claim 16, wherein the material of the second electrode layer comprises titanium nitride, and the stacked structure further comprises a ZrTiN layer located between the ZrON layer and the titanium nitride of the second electrode layer.

18. The method of fabricating the RRAM according to claim 9, wherein a material of the second electrode layer comprises titanium nitride, and the stacked structure further comprises a ZrTiN layer located between the ZrON layer and the titanium nitride of the second electrode layer.

19. The method of fabricating the RRAM according to claim 9, further comprising patterning the hafnium oxide layer and the zirconium layer before performing the annealing process.

20. The method of fabricating the RRAM according to claim 9, wherein the HfZrON layer is composed of a single material layer.

21. The method of fabricating the RRAM according to claim 9, wherein the HfZrON layer comprises a first material layer and a second material layer, and a mole ratio of nitrogen, oxygen, zirconium and hafnium in the first material layer is different from a mole ratio of nitrogen, oxygen, zirconium and hafnium in the second material layer.

22. A method of fabricating a resistance random access memory (RRAM), comprising:
providing a first electrode layer;
forming a stacked structure on the first electrode layer, the stacked structure comprising a HfZrON layer and a ZrON layer; and
forming a second electrode layer on the stacked structure,
wherein the HfZrON layer is located between the first electrode layer and the ZrON layer, the ZrON layer is located between the HfZrON layer and the second electrode layer, and the HfZrON layer and the ZrON layer are formed by deposition process.

23. The method of fabricating the RRAM according to claim 22, wherein materials of the first electrode layer and the second electrode layer respectively comprise metal nitrides or metals.

24. The method of fabricating the RRAM according to claim 23, wherein the stacked structure further comprises a HfTiON layer located between the HfZrON layer and the first electrode layer.

25. The method of fabricating the RRAM according to claim 24, wherein the stacked structure further comprises a ZrTiN layer located between the ZrON layer and titanium nitride of the second electrode layer.

26. The method of fabricating the RRAM according to claim 22, wherein the stacked structure further comprises a ZrTiN layer located between the ZrON layer and titanium nitride of the second electrode layer.

27. The method of fabricating the RRAM according to claim 22, wherein the HfZrON layer is composed of a single material layer.

28. The method of fabricating the RRAM according to claim 22, wherein the HfZrON layer comprises a first material layer and a second material layer, and a mole ratio of nitrogen, oxygen, zirconium and hafnium in the first material layer is different from a mole ratio of nitrogen, oxygen, zirconium and hafnium in the second material layer.
